(19) United States
(12) Patent Application Publication
(10) Pub. No.: US 2009/0267045 A1
(43) Pub. Date: Oct. 29, 2009

(54) PHASE CHANGE MEMORY DEVICE HAVING HEATERS AND METHOD FOR MANUFACTURING THE SAME

(76) Inventors: Heon Yong CHANG, Gyeonggi-do (KR); Hong Sun KIM, Chungcheongbuk-do (KR)

Correspondence Address: LADAS & PARRY LLP, 224 SOUTH MICHIGAN AVENUE, SUITE 1600, CHICAGO, IL, 60604, US

(21) Appl. No.: 12/211,196

(22) Filed: Sep. 16, 2008

(30) Foreign Application Priority Data
Apr. 28, 2008 (KR) 10-2008-0039517

(51) Int. Cl. H01L 45/00; H01L 21/06

(52) U.S. Cl. 257/3; 438/102; 257/E45.002; 257/E21.068

(57) ABSTRACT

A phase change memory device includes switching elements formed on a substrate that includes a cell region and a peripheral region. Heat sinks are formed on the switching elements. Heaters are formed on the heat sink and a phase change layer is formed on the heaters.

### CROSS-REFERENCE TO RELATED APPLICATIONS

The present application claims priority to Korean patent application number 10-2008-0039517 filed on Apr. 28, 2008, which is incorporated herein by reference in its entirety.

### BACKGROUND OF THE INVENTION

The present invention relates to a phase change memory device and a method for manufacturing the same, and more particularly, to a phase change memory device capable of increasing a sensing margin by forming heat sinks and a method for manufacturing the same.

Memory devices are largely divided into a volatile random access memory (RAM), which loses stored data when power is interrupted, and a non-volatile read-only memory (ROM), which is capable of continuously maintaining the stored state of inputted data even when power is interrupted. Volatile RAM includes several technologies, such as, a dynamic RAM (DRAM) and a static RAM (SRAM). The non-volatile ROM includes such technologies as a flash memory device, such as an electrically erasable and programmable ROM (EEPROM).

The DRAM requires a high charge storing capacity, and therefore, the surface area of an electrode must be increased, and therefore accomplishing a high level of integration is difficult. Further, in the flash memory device, two gates are stacked upon each other, and therefore a high operation voltage is required as compared to a power source voltage. As a result a separate booster circuit is required to supply the voltage for write and delete operations, also making a high level of integration difficult.

As such, a novel memory device having a simple configuration and capable of accomplishing a high level of integration, while retaining the characteristics of the non-volatile memory device, is needed. A phase change memory device has been explored in this regard.

In the conventional phase change memory device, a phase change layer is interposed between a bottom electrode and a upper electrode. When a current is flowed between the upper and bottom electrodes, a phase change from a crystalline state to an amorphous state occurs in the phase change layer. Information is stored in a cell, and the information is recognized, using a difference in resistance between the crystalline state and the amorphous state. The specific resistance of the phase change layer in the amorphous state is higher than the specific resistance of the phase change layer in the crystalline state. In a read mode it is determined whether the information stored in a phase change cell has a logic value of ‘1’ or ‘0’ by sensing the current flowing through the phase change layer.

However, in the conventional art, when cooling the phase change layer, so as to change the phase of the phase change memory device to a reset state, the phase change layer may not be appropriately cooled due to delay of a cooling speed, and as a result, the phase change layer will be in an intermediate state between the amorphous state and the crystalline state.

That is, because the phase change layer is present in the intermediate state between the amorphous state and the crystalline state, in the conventional art, the reset resistance of the phase change memory device reduced. Accordingly, as the difference between set resistance and reset resistance decreases in the phase change memory device, a sensing margin deteriorates.

### SUMMARY OF THE INVENTION

Embodiments of the present invention are include a phase change memory device which can increase a sensing margin, and a method for manufacturing the same.

In one embodiment of the present invention, a phase change memory device comprises heat sinks formed between heaters and switching elements.

The heat sinks comprise any one of a tungsten layer, a tungsten silicide layer, and a titanium nitride layer.

In another embodiment of the present invention, a phase change memory device comprises switching elements formed on a semiconductor substrate; heat sinks formed on the switching elements; heaters formed on the heat sinks; and a phase change layer formed on the heaters.

The switching elements comprise vertical PN diodes.

The phase change memory device further comprises an impurity region formed in a surface of the semiconductor substrate to contact the switching elements.

The phase change memory device further comprises a punch stop ion implantation layer and a field stop ion implantation layer sequentially placed under the impurity region in the semiconductor substrate.

The heat sinks comprise any one of a tungsten layer, a tungsten silicide layer, and a titanium nitride layer.

The phase change memory device further comprises a hard mask layer formed on sidewalls of the heaters.

The phase change memory device further comprises an insulation layer interposed between the hard mask layer and the phase change layer.

The insulation layer comprises a nitride layer.

The phase change memory device further comprises upper electrodes formed on the phase change layer; and a protective layer formed to cover the upper electrodes and the phase change layer.

In another aspect of the present invention, a method for manufacturing a phase change memory device comprises the steps of forming switching elements on a semiconductor substrate; forming heat sinks on the switching elements; forming heaters on the heat sinks; and forming a phase change layer on the heaters.

The switching elements are formed as vertical PN diodes.

Before the step of forming the switching elements, the method further comprises the step of forming an impurity region in a surface of the semiconductor substrate.

The heat sinks comprise any one of a tungsten layer, a tungsten silicide layer, and a titanium nitride layer.

After the step of forming the phase change layer, the method further comprises the steps of forming upper electrodes on the phase change layer; and forming a protective layer to cover the upper electrodes and the phase change layer.

In still another embodiment of the present invention, a method for manufacturing a phase change memory device comprises the steps of forming an interlayer dielectric having contact holes in a cell region of a semiconductor substrate which has the cell region and a peripheral region; forming a first conductivity type polysilicon layer on the semiconductor substrate including the interlayer dielectric, to fill the contact holes; forming vertical PN diodes by ion-implanting second conductivity type impurities into an upper end of the first conductivity type polysilicon layer formed in the contact holes in the cell region; forming a conductive layer on the semiconductor substrate including the cell region in which the vertical PN diodes are formed; etching the conductive layer and the first conductivity type polysilicon layer and thereby forming heat sinks on the vertical PN diodes in the cell region and gates on the semiconductor substrate in the peripheral region; forming heaters on the heat sinks in the cell region; and forming a phase change layer on the heaters.

Before the step of forming the interlayer dielectric, the method further comprises the step of forming an impurity region in a surface of the semiconductor substrate in the cell region.

The step of forming the first conductivity type polysilicon layer comprises the steps of depositing a first conductivity type polysilicon layer on the semiconductor substrate including the interlayer dielectric to fill the contact holes; and CMPing the first conductivity type polysilicon layer until the interlayer dielectric is exposed.

After the step of forming the conductive layer and before the step of forming the heat sinks and the gates, the method further comprises the step of forming a hard mask layer on the conductive layer.

The heat sinks comprise any one of a tungsten layer, a tungsten silicide layer, and a titanium nitride layer.

After the step of forming the heat sinks and the gates and before the step of forming the heaters, the method further comprises the step of forming an insulation layer on the semiconductor substrate formed with the heat sinks and the gates to cover the heat sinks and the gates.

The insulation layer comprises a nitride layer.

After the step of forming the phase change layer, the method further comprises the steps of forming upper electrodes on the phase change layer; and forming a protective layer to cover the upper electrodes and the phase change layer.

In a another embodiment of the present invention, a method for manufacturing a phase change memory device comprises the steps of forming an interlayer dielectric having contact holes in a cell region of a semiconductor substrate which has the cell region and a peripheral region, such that the contact holes expose portions of the cell region; forming a first conductivity type epi-silicon layer in the contact holes in the cell region; removing a portion of the interlayer dielectric which is formed in the peripheral region; forming a polysilicon layer in the peripheral region from which the interlayer dielectric is removed; forming vertical PN diodes by ion-implanting second conductivity type impurities into an upper end of the first conductivity type epi-silicon layer formed in the contact holes in the cell region; forming a conductive layer on the semiconductor substrate including the cell region in which the vertical PN diodes are formed; etching the conductive layer and the polysilicon layer and thereby forming heat sinks on the vertical PN diodes in the cell region and gates on the semiconductor substrate in the peripheral region; forming heaters on the heat sinks in the cell region; and forming a phase change layer on the heaters.

Before the step of forming the interlayer dielectric, the method further comprises the step of forming an impurity region in a surface of the semiconductor substrate in the cell region.

Before the step of forming the impurity region, the method further comprises the step of forming a punch stop ion implantation layer and a field stop ion implantation layer in the semiconductor substrate such that they are sequentially placed under the impurity region.

The step of forming the first conductivity type epi-silicon layer comprises the steps of growing a first conductivity type epi-silicon layer from the exposed portions of the cell region; and CMPing the grown first conductivity type epi-silicon layer until the interlayer dielectric is exposed.

The step of forming the polysilicon layer in the peripheral region comprises the steps of depositing a polysilicon layer on the semiconductor substrate including the peripheral region from which the interlayer dielectric is removed; and CMPing the polysilicon layer until the interlayer dielectric in the cell region is exposed.

The step of forming the polysilicon layer in the peripheral region comprises the steps of depositing a polysilicon layer on the semiconductor substrate including the peripheral region from which the interlayer dielectric is removed; forming a mask pattern to expose a portion of the polysilicon layer which is formed in the cell region; etching the portion of the polysilicon layer exposed in the cell region; and removing the mask pattern.

After the step of forming the conductive layer and before the step of forming the heat sinks and the gates, the method further comprises the step of forming a hard mask layer on the conductive layer.

The heat sinks comprise any one of a tungsten layer, a tungsten silicide layer, and a titanium nitride layer.

After the step of forming the heat sinks and the gates and before the step of forming the heaters, the method further comprises the step of forming an insulation layer on the semiconductor substrate formed with the heat sinks and the gates to cover the heat sinks and the gates.

The insulation layer comprises a nitride layer.

After the step of forming the phase change layer, the method further comprises the steps of forming upper electrodes on the phase change layer; and forming a protective layer to cover the upper electrodes and the phase change layer.

### BRIEF DESCRIPTION OF THE DRAWINGS

FIG. 1 is a cross-sectional view showing a phase change memory device in accordance with an embodiment of the present invention.

FIGS. 2A through 2K are cross-sectional views showing the steps of a method for manufacturing the phase change memory device in accordance with an embodiment of the present invention.

FIGS. 3A through 3M are cross-sectional views showing the steps of a method for manufacturing a phase change memory device in accordance with another embodiment of the present invention.

### DESCRIPTION OF SPECIFIC EMBODIMENTS

In the present invention, heat sinks are formed between heaters and switching elements using a material having high heat conductivity. According to this, in the present invention, when cooling a phase change layer so as to change the phase of a phase change memory device to a reset state, the phase change layer is cooled at an increased rate when compared to the conventional art. Through this, the amorphous phase of the phase change layer of the present invention can be maintained during the reset state of the phase change memory device.

Therefore, in the present invention, the difference between set resistance and reset resistance can be increased, and the sensing margin of the phase change memory device can be increased, because a high reset resistance can be maintained due to the heat sinks of the present invention. Also, in the present invention, by forming the heat sinks on the same layer as a gate conductive layer in a peripheral region, manufacturing processes are simplified, and the thickness of the contacts formed in the peripheral region can be decreased.

Hereafter, specific embodiments of the present invention will be described in detail with reference to the accompanying drawings.

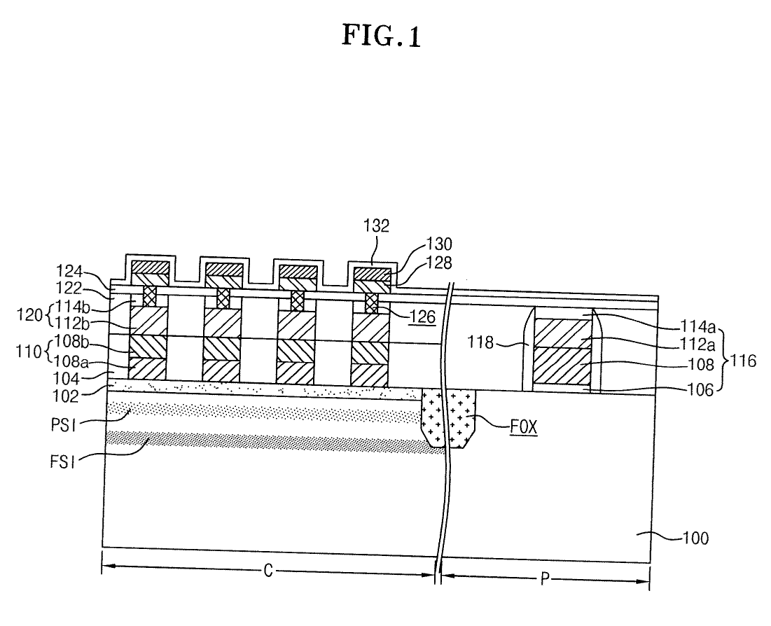

FIG. 1 is a cross-sectional view showing a phase change memory device in accordance with an embodiment of the present invention.

Referring to FIG. 1, an isolation structure FOX is formed in a semiconductor substrate 100, which includes a cell region C and a peripheral region P, to delimit active areas in the respective regions. An impurity region 102 is formed beneath the surface of the semiconductor substrate 100 in the cell region C. The impurity region 102 comprises, for example, an N-type impurity region. A punch stop ion implantation layer PSI and a field stop ion implantation layer FSI may be formed in the semiconductor substrate 100 beneath the impurity region 102, so that they are sequentially placed under the surface of the semiconductor substrate 100.

Vertical PN diodes 110 serving as switching elements are formed on the impurity region 102 in the cell region C. Preferably, the vertical PN diodes 110 include the stacked structure of an N-type area 108a and a P-type area 108b. Heat sinks 120 are formed on the vertical PN diodes 110 in the cell region C. The heat sinks 120 include the stacked structure of a conductive layer 112b and a hard mask layer 114b. The conductive layer 112b comprises a tungsten layer, a tungsten silicide layer, a titanium nitride layer, or other similar material having high heat conductivity.

Heaters 126 are formed on the heat sinks 120, that is, through the hard mask layer 114b, to contact the conductive layer 112b. A phase change layer 128 and an upper electrode 130 are sequentially formed on the heater 126. A second insulation layer 124 may be interposed between the hard mask layer 114b and the phase change layer 128. In this case, the second insulation layer 124 comprises, a nitride layer or the like.

A protective layer 132 is formed on the phase change layer 128, upper electrodes 130, and the second insulation layer 124, so as to cover the upper electrodes 130 and the phase change layer 128. The protective layer 132 functions to prevent the dissipation of heat transferred from the heaters 126 to the phase change layer 128.

A gate 116 is formed on the semiconductor substrate 100 in the peripheral region P. The gate 116 includes a gate insulation layer 106, a polysilicon layer 108, a gate conductive layer 112a, and a gate hard mask layer 114a. Spacers 118 are formed on both sidewalls of the gate 116.

In FIG. 1, the reference numeral 104 designates an interlayer dielectric and the reference numeral 122 designates a first insulation layer.

As described above, in the phase change memory device in accordance with an embodiment of the present invention, the heat sinks 120 are formed between the vertical PN diodes 110 and the heaters 126 using a material having high heat conductivity, and therefore, when resetting the phase change memory device, the cooling speed of the phase change layer 128 increases such that the amorphous phase of the phase change layer 128 is maintained.

Therefore, in the present invention, since a high reset resistance is maintained, the difference between set resistance and reset resistance is increased, and accordingly, the sensing margin of the phase change memory device is increased.

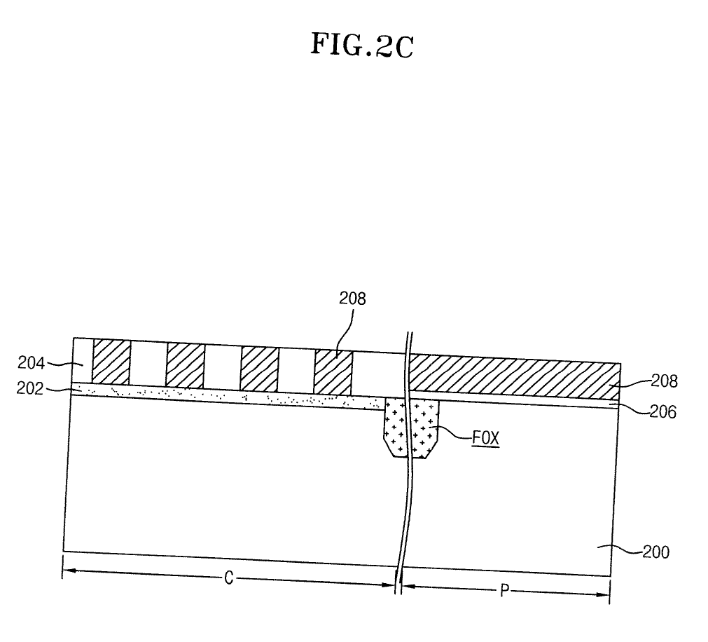

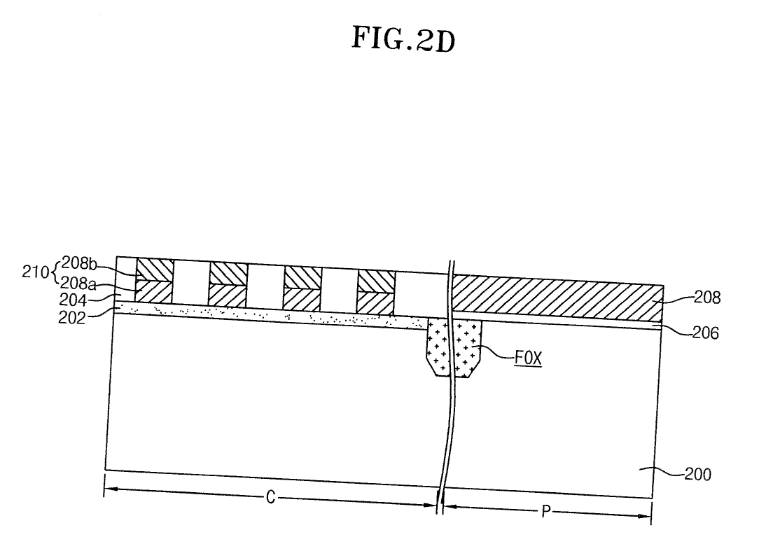

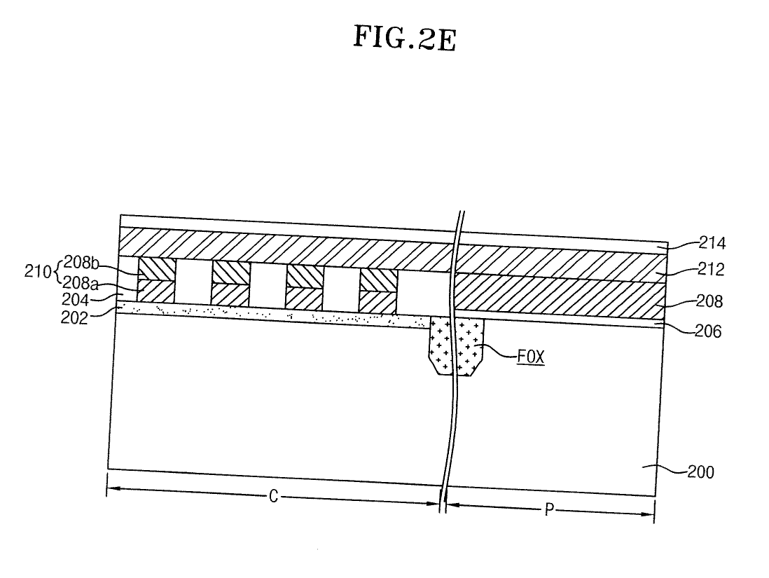

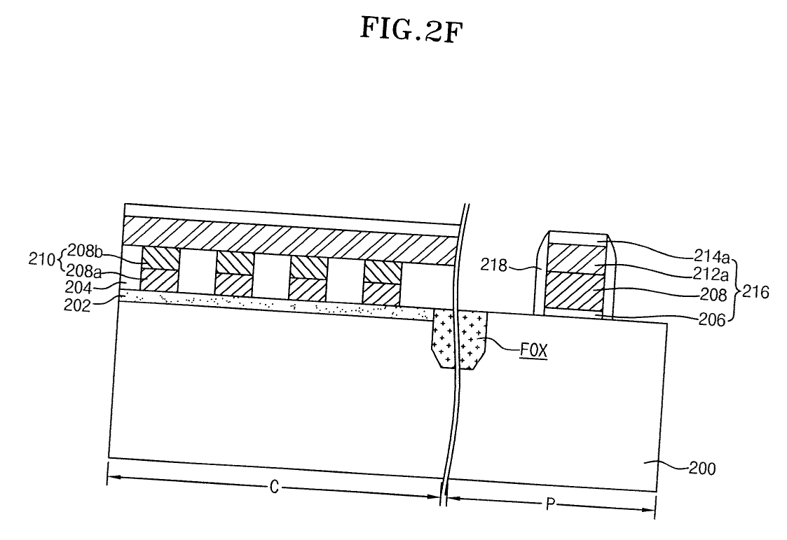

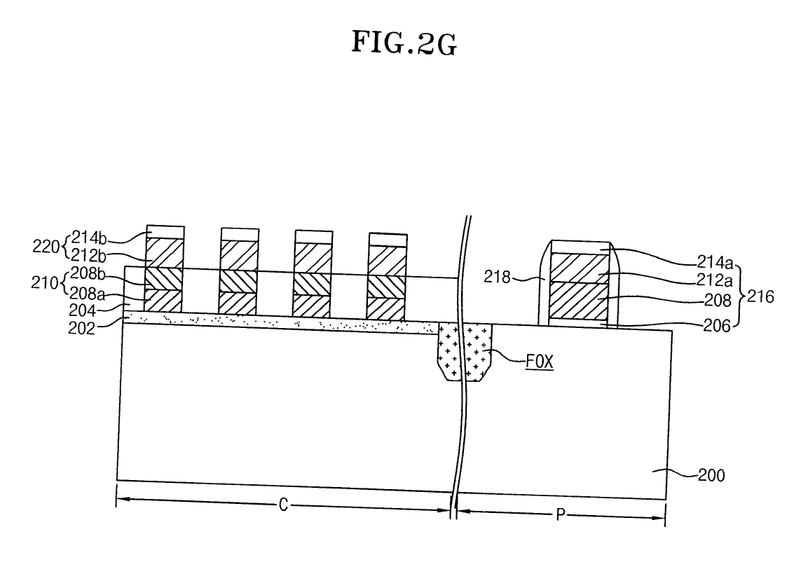

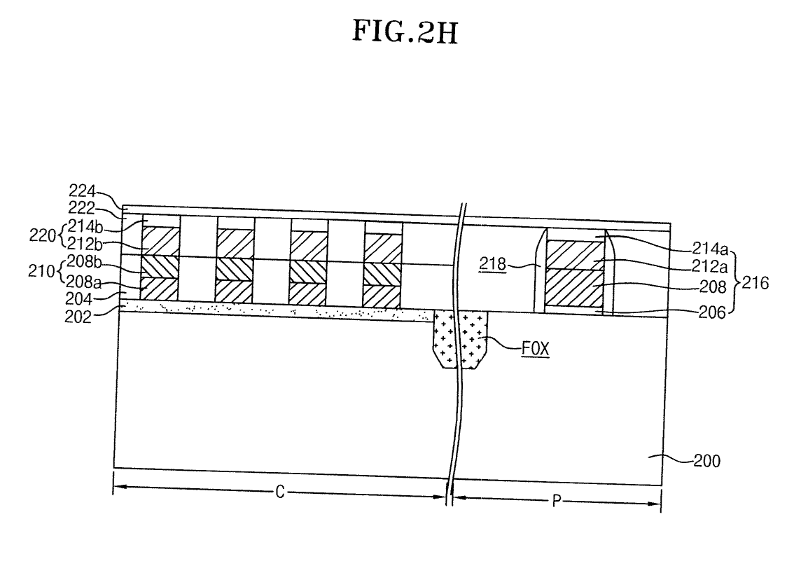

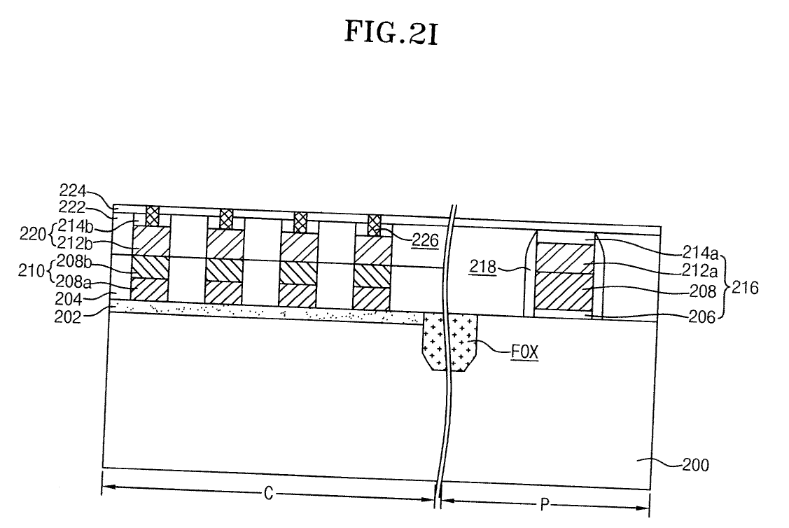

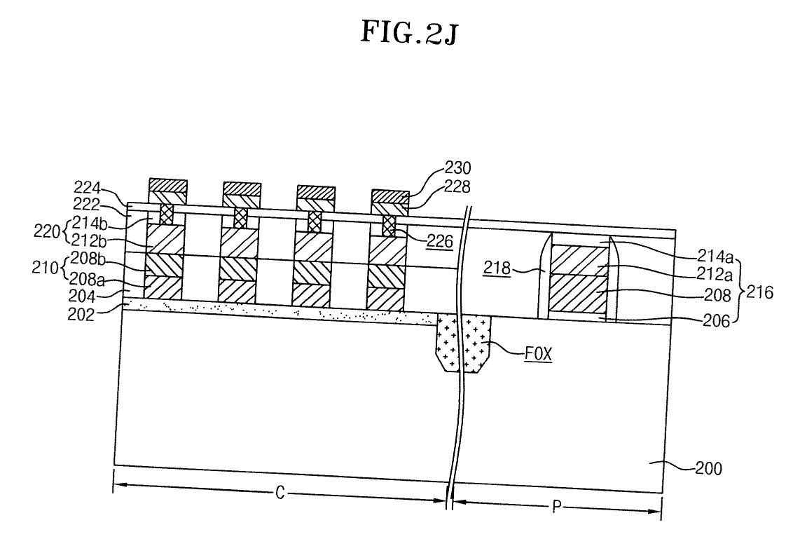

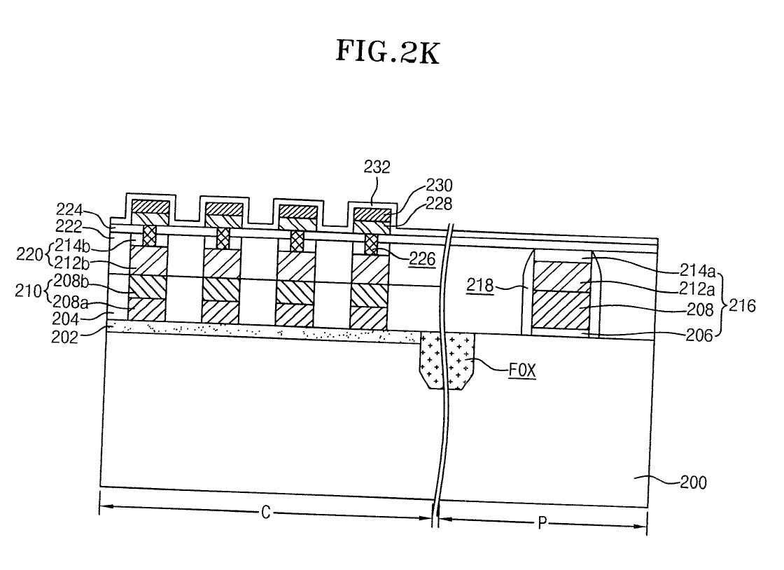

FIGS. 2A through 2K are cross-sectional views showing the steps of a method for manufacturing a phase change memory device in accordance with an embodiment of the present invention.

Referring to FIG. 2A, an isolation structure FOX is formed in a semiconductor substrate 200 which has a cell region C and a peripheral region P, to delimit active areas in the respective regions. An impurity region 202 is formed in the cell region C of the semiconductor substrate 200, beneath the upper surface of the semiconductor substrate 200, by conducting an ion implantation process. The ion implantation process is conducted using N-type impurities, for example, P or As, preferably, at an energy level of 10˜100 keV. As a result of the ion implantation process, the impurity region 202, having a concentration of 1×10²⁰˜1×10²² ions/cm³, is formed into the surface of the semiconductor substrate 200 in the cell region C. An interlayer dielectric 204 is formed on the semiconductor substrate 200, which includes the impurity region 202 in the cell region C thereof.

Referring to FIG. 2B, a gate insulation layer 206 is formed on the semiconductor substrate 200 and the interlayer dielectric 204. A plurality of contact holes H are defined in the cell region C to expose the impurity region 202 by etching the gate insulation layer 206 and the interlayer dielectric 204 in the cell region C.

Referring to FIG. 2C, a first conductivity type polysilicon layer, for example N-type polysilicon layer 208 is deposited on the semiconductor substrate 200 including the interlayer dielectric 204 to fill the contact holes H. Then the N-type polysilicon layer 208 and the gate insulation layer 206 are chemically mechanically polished (CMPed) until the interlayer dielectric 204 is exposed as shown in FIG. 2c. For example, the N-type polysilicon layer 208 is formed to have a concentration of 1×10¹⁸˜1×10²² ions/cm³.

In an embodiment of the present invention, the N-type polysilicon layer 208 is formed simultaneously in the cell region C and in the peripheral region P. The N-type polysilicon layer 208 is used in the cell region C as a material for the N-type areas of vertical PN diodes, which will be subsequently formed, and in the peripheral region P as a conductive layer. Therefore, in the present embodiment, manufacturing processes can be simplified. Also, in the present embodiment, by chemically mechanically polishing (CMPing) the N-type polysilicon layer 208 to remove undulations present in the cell region C and the peripheral region P, subsequent photo processes and etching processes can be easily conducted.

Referring to FIG. 2D, a second conductivity type ion implantation process, for example a p-type ion implantation process is conducted on an upper portion of the N-type polysilicon layer 208, which is formed within the contact holes H in the cell region C. For example, the P-type ion implantation process is conducted using B or BF₂, preferably, at an energy level of 10˜100 keV. As a result of this, the upper portion of the N-type polysilicon layer 208 is converted into a P-type polysilicon layer having a concentration of 1×10²⁰˜1×10²² ions/cm³. Accordingly, vertical PN diodes 210, which have the stacked structure of an N-type area 208a and a P-type area 208b, are formed in the contact holes H in the cell region C and serve as switching elements.

Referring to FIG. 2E, a conductive layer 212 and a hard mask layer 214 are sequentially formed on the vertical PN diodes 210 and the interlayer dielectric 204 in the cell region C and on the N-type polysilicon layer 208 in the peripheral region P. Preferably, the conductive layer 212 comprises a tungsten layer, a tungsten silicide layer, a titanium nitride layer, or a layer of some other similar material.

Referring to FIG. 2F, a gate 216 is formed on the semiconductor substrate 200 in the peripheral region P by etching the hard mask layer 214, the conductive layer 212, the N-type polysilicon layer 208, and the gate insulation layer 206 in the peripheral region P. The gate 216 has the stacked structure of the gate insulation layer 206, the N-type polysilicon layer 208, a conductive layer 212a, and a hard mask layer 214a. Then, spacers 218 are formed on both sidewalls of the gate 216.

Referring to FIG. 2G, heat sinks 220 are formed on the vertical PN diodes 210 in the cell region C by etching the hard mask layer 214 and the conductive layer 212 in the cell region C. The heat sinks 220 have the stacked structure of a conductive layer 212b and a hard mask layer 214b. Here, since the heat sinks 220 are formed on the vertical PN diodes 210 using a material having high heat conductivity, the heat transferred to a phase change layer when resetting the phase change memory device, (the forming phase change layer will be explained below) can be quickly dissipated so that the phase change layer can maintain the amorphous phase. The gate 216 and the heat sinks 220 can be formed in the reverse sequence or simultaneously.

Referring to FIG. 2H, a first insulation layer 222 is formed on the resultant semiconductor substrate 200, having the gate 216 and the heat sinks 220, to cover the gate 216 and the heat sinks 220, then the first insulation layer 222 is CMPed until the gate 216 and the heat sinks 220 are exposed. Subsequently, a second insulation layer 224 is formed on the CMPed first insulation layer 222. The second insulation layer 224 comprises, for example, a nitride layer, and preferably, is formed to a thickness of 500˜2,000 Å. The formation of the second insulation layer 224 may optionally be omitted.

Referring to FIG. 2I, holes are defined by etching the second insulation layer 224 and the hard mask layer 214b such that the hole expose the conductive layer 212b. Subsequently, heaters 226 are formed in the holes in such a way as to contact the conductive layer 212b. For example, the heaters 226 may comprise a titanium nitride layer, a titanium tungsten layer, a titanium aluminum nitride layer, a tungsten nitride layer, or a layer of some other similar material.

Referring to FIG. 2J, a phase change layer 228 and upper electrodes 230 are formed on the second insulation layer 224 including the heaters 226 in such a way as to contact the heaters 226. The phase change layer 228 is formed of a material containing a chalcogen element, for example, a compound containing at least one of germanium (Ge), stibium or antimony (Sb) and tellurium (Te), or an alloy of these elements. It is conceivable that at least one of oxygen, nitrogen, and silicon can be implanted into the elements. The upper electrodes 230 are preferably formed of the same material as the heaters 226. Alternatively, the upper electrodes 230 can be formed of other materials. It is preferred that the upper electrodes 230 and the phase change layer 228 be formed to be aligned so as to minimize etch loss.

Referring to FIG. 2K, a protective layer 232 is formed over the upper electrodes 230, the phase change layer 228, and the second insulation layer 224 to cover the upper electrodes 230 and the phase change layer 228. The protective layer 232 functions to prevent dissipation of the heat transferred to the phase change layer 228.

Thereafter, while not shown in the drawings, by sequentially implementing a series of well-known subsequent processes, the manufacture of the phase change memory device in accordance with an embodiment of the present invention is completed.

As is apparent from the above description, in an embodiment of the present invention, heat sinks are formed on vertical PN diodes, and as such, when cooling a phase change layer so as to change the phase of a phase change memory device to a reset state, the cooling speed of the phase change layer is increased when compared to the conventional art. Through this, in an embodiment of the present invention, in the reset state of the phase change memory device, the amorphous phase of the phase change layer can be maintained in a stable way. Therefore, in an embodiment of the present invention, high reset resistance is maintained, and therefore the difference between set resistance and reset resistance is increased. As a result, in the present invention, the sensing margin of the phase change memory device can be effectively increased.

Further, in an embodiment of the present invention, because a conductive layer is formed simultaneously when forming a conductive layer, manufacturing processes can be simplified, and through this, the manufacturing yield of a phase change memory device can be increased.

Meanwhile, while it was described in an embodiment of the present invention that vertical PN diodes are formed by depositing a polysilicon layer, it is conceivable that, in another embodiment of the present invention, the vertical PN diodes can be formed by growing an epi-silicon layer and a punch stop ion implantation layer and a field stop ion implantation layer can be formed in a semiconductor substrate.

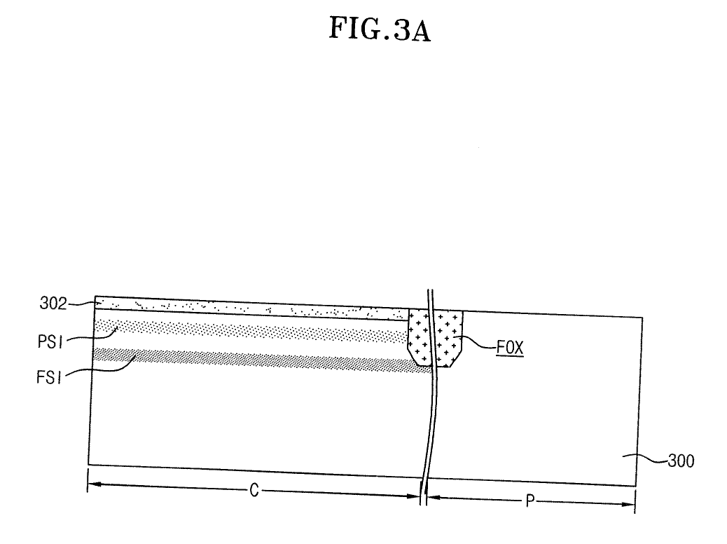

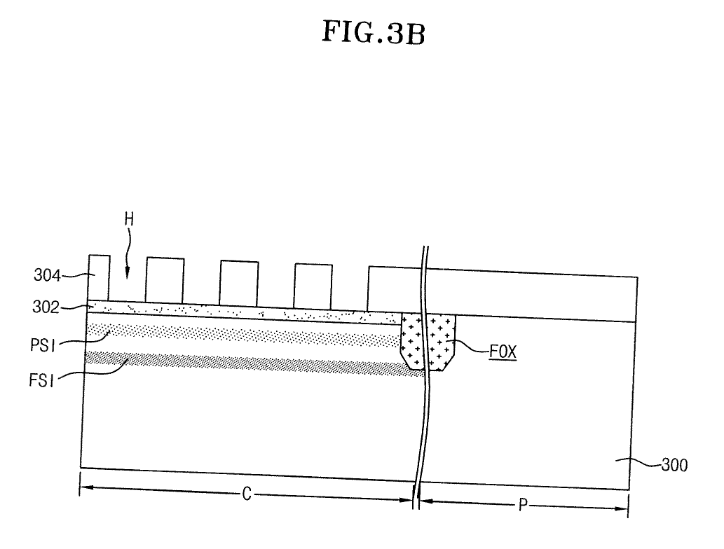

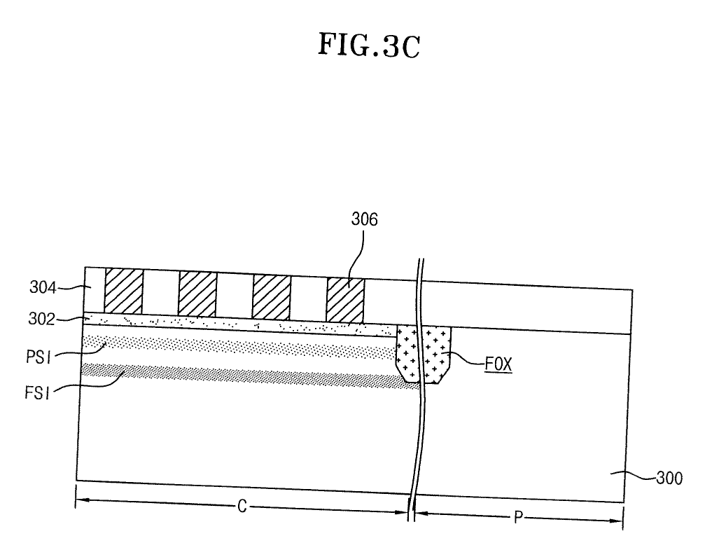

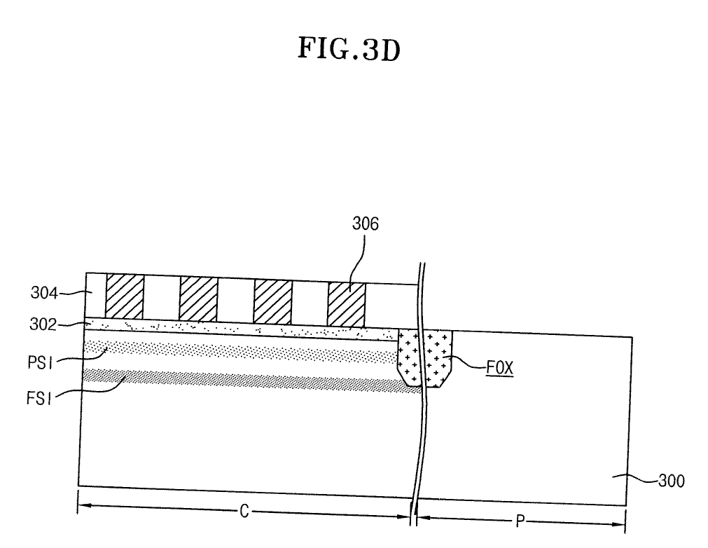

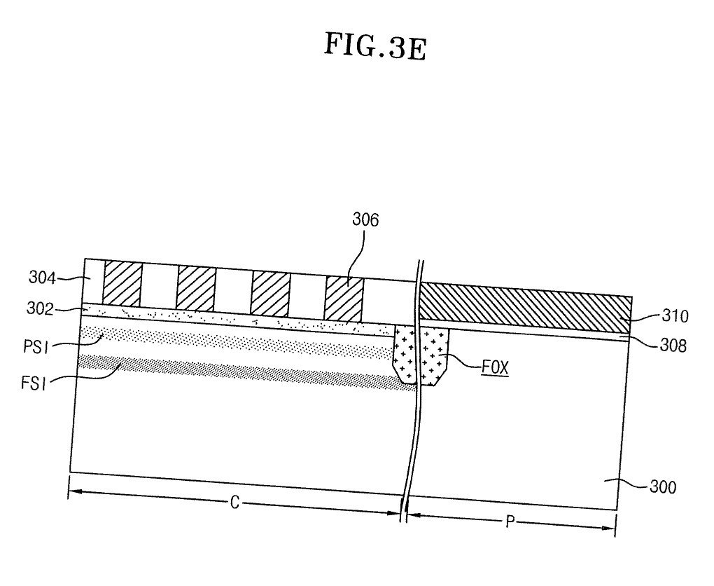

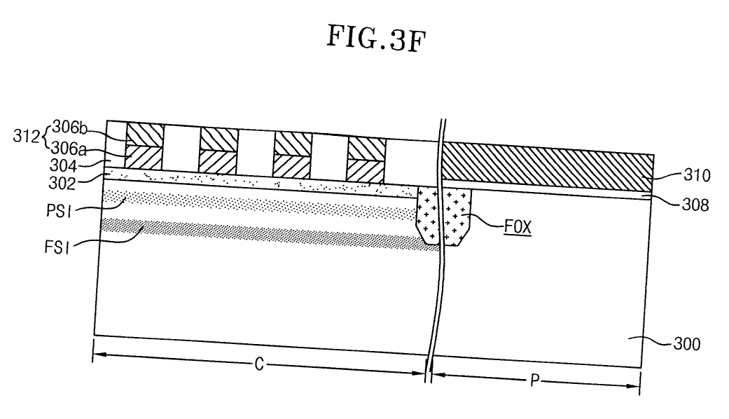

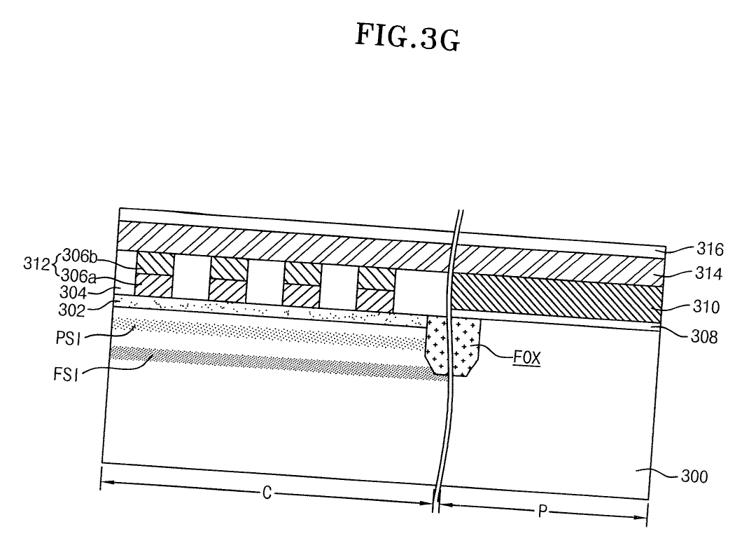

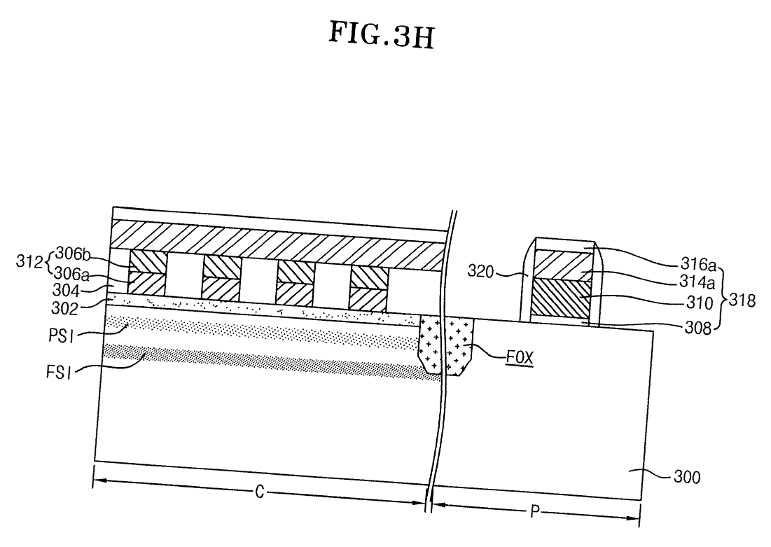

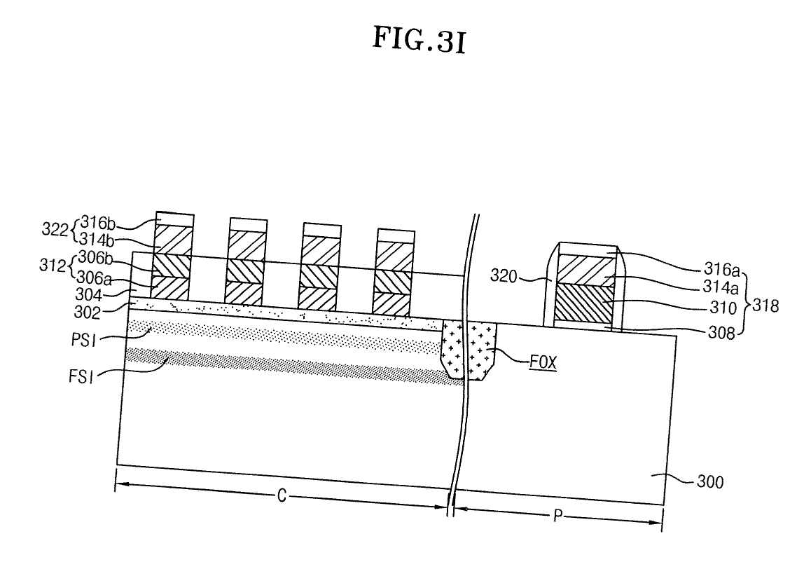

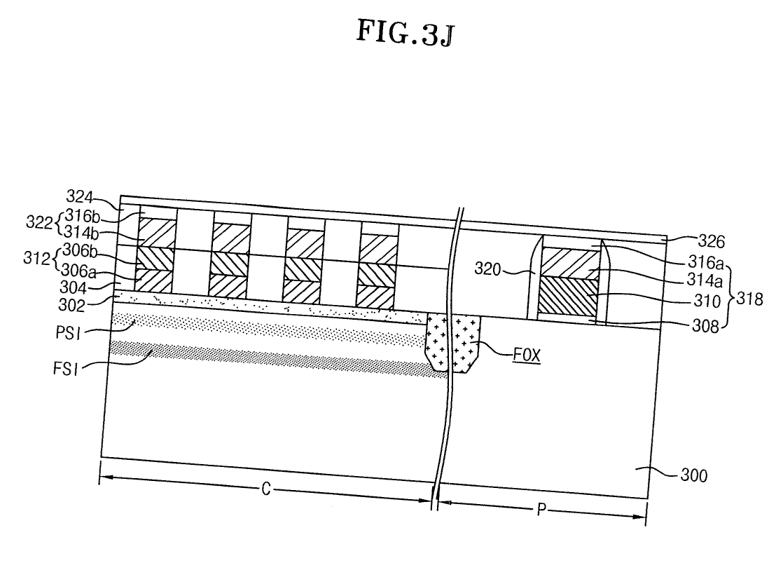

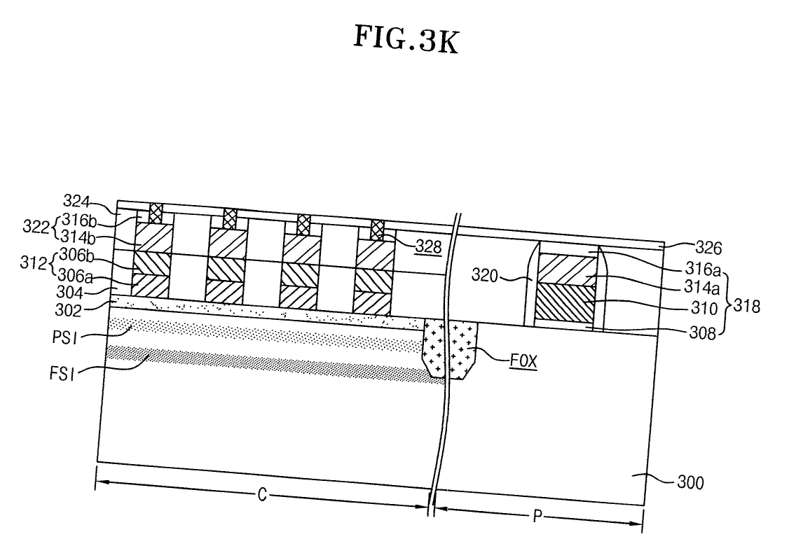

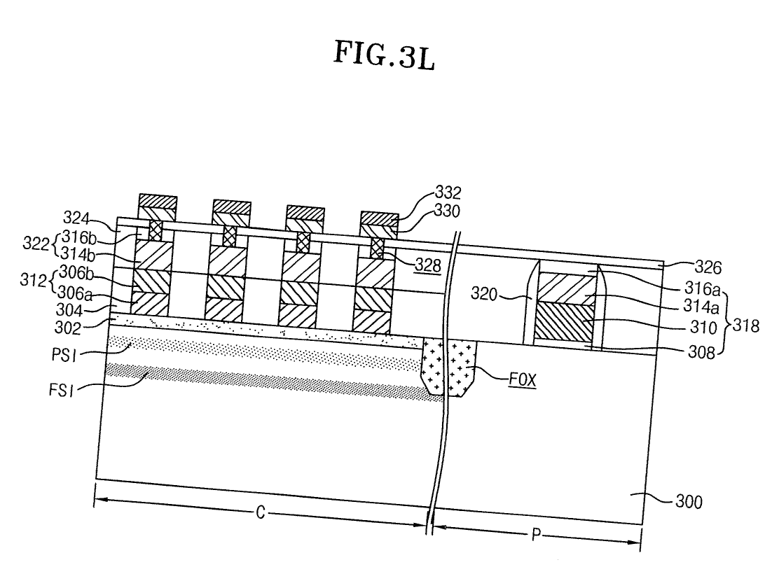

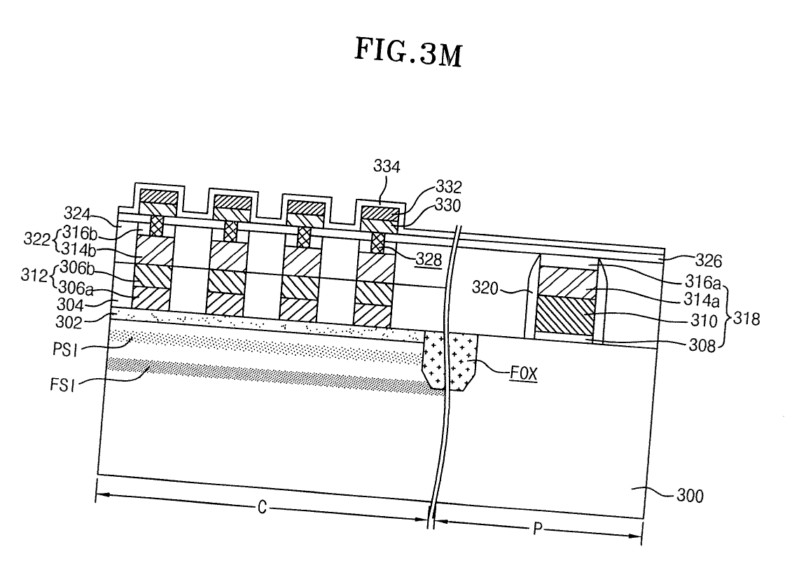

FIGS. 3A through 3M are cross-sectional views showing the steps of a method for manufacturing a phase change memory device in accordance with another embodiment of the present invention.

Referring to FIG. 3A, an isolation structure FOX is formed in a semiconductor substrate 300, which includes a cell region C and a peripheral region P, so as to delimit active areas in the respective regions. A punch stop ion implantation layer PSI and a field stop ion implantation layer FSI are formed by conducting a second conductivity type ion implantation process, for example a P-type ion implantation process, on the semiconductor substrate 300 in the cell region C. The punch stop ion implantation layer PSI and the field stop ion implantation layer FSI are sequentially formed beneath the surface of the semiconductor substrate 300. The P-type ion implantation process is conducted using, for example, B or BF₂.

An impurity region 302 is formed in the cell region C of the semiconductor substrate 300, beneath the upper surface of the semiconductor substrate 300, by conducting an ion implantation process of a first conductivity type, for example, N-type. The N-type ion implantation process is conducted at an energy level lower than that of the P-type ion implantation process, preferably, at an energy level of 10˜100 keV. The impurity region 302, having a concentration of 1×10²⁰1×10²² ions/cm³ is formed into the surface of the semiconductor substrate 300 in the cell region C over the punch stop ion implantation layer PSI. Alternatively, the P-type ion implantation process and the N-type ion implantation process may be conducted in the reverse sequence.

Referring to FIG. 3B, an interlayer dielectric 304 is formed on the semiconductor substrate 300, which is formed with the punch stop ion implantation layer PSI, the field stop ion implantation layer FSI, and the impurity region 302. Subsequently, a plurality of contact holes H are defined in the cell region C to expose the impurity region 302 by etching the interlayer dielectric 304 in the cell region C.

Referring to FIG. 3C, a first conductivity type, epi-silicon layer, for example N-type epi-silicon layer 306, is grown from the impurity region 302 in the cell region C, which is exposed through the contact holes H. The N-type epi-silicon layer 306 is grown, for example, through selective epitaxial growth (SEG). The N-type epi-silicon layer 306 is grown to have an ion concentration lower than that of the impurity region 302, preferably, of 1×10¹⁸˜1×10²⁰ ions/cm³. The N-type epi-silicon layer 306 is CMPed until the interlayer dielectric 304 is exposed. As a result, the contact holes H in the cell region C are filled with the N-type epi-silicon layer 306, which has preferably a thickness of 500˜2,000 Å.

Referring to FIG. 3D, the portion of the interlayer dielectric 304, which is formed in the peripheral region P, is removed so as to expose the surface of the semiconductor substrate 300 in the peripheral region P.

Referring to FIG. 3E, a gate insulation layer 308 is formed on the semiconductor substrate 300 in the peripheral region P, which is exposed due to the removal of the interlayer dielectric 304 The gate insulation layer 308 is also formed on the N-type epi-silicon layer 306 and the interlayer dielectric 304 in the cell region C. A polysilicon layer 310 is deposited on the gate insulation layer 308 as a gate conductive layer, and then the polysilicon layer 310 and the gate insulation layer 308 are CMPed until the interlayer dielectric 304 in the cell region C is exposed. As a result, the polysilicon layer 310 and the gate insulation layer 308 in the cell region C are removed, and a step portion (i.e., a height difference) between the cell region C and the peripheral region P is removed.

Alternatively, the removal of the polysilicon layer 310 and the gate insulation layer 308 in the cell region C can be implemented as described below in place of the CMPing. That is, a mask pattern (not shown) is formed on the polysilicon layer 310 to expose the cell region C. Then, after etching the polysilicon layer 310 and the gate insulation layer 308 in the exposed cell region C, the mask pattern is removed.

Referring to FIG. 3F, a second conductivity type ion implantation process, for example a P-type ion implantation process, is conducted on an upper portion of the N-type epi-silicon layer 306 formed in the contact holes H in the cell region C. The P-type impurity ion implantation process is conducted using, for example, B or BF₂, preferably, at an energy level of 10˜100 keV. As a result, the upper portion of the N-type epi-silicon layer 306 is converted into a P-type epi-silicon layer having a concentration of 1×10²⁰˜1×10²² ions/cm³. Vertical PN diodes 312 serving as switching elements are formed in the contact holes H in the cell region C as a result of the above process, such that the vertical PN diodes 312 have the stacked structure of an N-type area 306a and a P-type area 306b.

Referring to FIG. 3G, a conductive layer 314 and a hard mask layer 316 are sequentially formed on the vertical PN diodes 312 and the interlayer dielectric 304 in the cell region C and also on the polysilicon layer 310 in the peripheral region P. Preferably, the conductive layer 314 comprises a tungsten layer, a tungsten silicide layer, and a titanium nitride layer, or a layer of another such material.

Referring to FIG. 3H, a gate 318 is formed on the semiconductor substrate 300 in the peripheral region P by etching the hard mask layer 316, the conductive layer 314, the polysilicon layer 310, and the gate insulation layer 308 in the peripheral region P. The gate 318 has the stacked structure of the gate insulation layer 308, the polysilicon layer 310, a conductive layer 314a, and a hard mask layer 316a. Subsequently, spacers 320 are formed on both sidewalls of the gate 318.

Referring to FIG. 3I, heat sinks 322 are formed on the vertical PN diodes 312 in the cell region C by etching the hard mask layer 316 and the conductive layer 314 in the cell region C. The heat sinks 322 have the stacked structure of a conductive layer 314b and a hard mask layer 316b. Here, since the heat sinks 322 are formed on the vertical PN diodes 312 using a material having high heat conductivity, when resetting the phase change memory device, the heat transferred to a phase change layer (which is subsequently formed) can be quickly dissipated so that the phase change layer can maintain the amorphous phase. The gate 318 and the heat sinks 322 can be formed in the reverse sequence or simultaneously.

Referring to FIG. 3J, a first insulation layer 324 is formed on the semiconductor substrate 300, which includes the gate 318 and the heat sinks 322, to cover the gate 318 and the heat sinks 322, and then the first insulation layer 324 is CMPed until the gate is 318 and the heat sinks 322 are exposed. Subsequently, a second insulation layer 326 is formed on the CMPed first insulation layer 324. The second insulation layer 326 may include, for example, a nitride layer, and preferably, the second insulation layer 326 is formed to a thickness of 500˜2,000 Å. The formation of the second insulation layer 326 may be omitted.

Referring to FIG. 3K, holes are defined by etching the second insulation layer 326 and the hard mask layer 316b so as to expose the conductive layer 314b. Subsequently, heaters 328 are formed in the holes in such a way as to contact the conductive layer 314b. For example, the heaters 328 comprise a titanium nitride layer, a titanium tungsten layer, a titanium aluminum nitride layer, a tungsten nitride layer, or other similar material.

Referring to FIG. 3L, a phase change layer 330 and upper electrodes 332 are formed on the second insulation layer 326 and the heaters 328 in such a way as to contact the heaters 328. The phase change layer 330 is formed of a material containing a chalcogen element, for example, a compound containing at least one of germanium (Ge), stibium (Sb) and tellurium (Te) or an alloy of these elements. It is conceivable that at least one of oxygen, nitrogen and silicon can be implanted into the elements. The upper electrodes 332 are preferably formed of the same material as the heaters 328. Alternatively, the upper electrodes 332 can be formed of other materials. It is preferred that the upper electrodes 332 and the phase change layer 330 are aligned in order to minimize etch loss.

Referring to FIG. 3M, a protective layer 334 is formed on the upper electrodes 332, the phase change layer 330, and the second insulation layer 326 to cover the upper electrodes 332 and the phase change layer 330. The protective layer 334 functions to prevent the dissipation of the heat transferred to the phase change layer 330.

Thereafter, while not shown in the drawings, by sequentially implementing a series of well-known subsequent processes, the manufacture of the phase change memory device in accordance with another embodiment of the present invention is completed.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A phase change memory device comprising:
heat sinks interposed between heaters and switching elements.

2. The phase change memory device according to claim 1, wherein the heat sinks comprise at least one of a tungsten layer, a tungsten silicide layer, and a titanium nitride layer.

3. A phase change memory device comprising:
switching elements formed on a semiconductor substrate;
heat sinks formed on the switching elements;
heaters formed on the heat sinks; and
a phase change layer formed on the heaters.

4. The phase change memory device according to claim 3, wherein the switching elements comprise vertical PN diodes.

5. The phase change memory device according to claim 3, further comprising:
an impurity region formed within a surface of the semiconductor substrate contacting the switching elements.

6. The phase change memory device according to claim 5, further comprising:
a punch stop ion implantation layer; and
a field stop ion implantation layer,
wherein the punch stop ion implantation layer and the field stop ion implantation layer are formed sequentially in the semiconductor substrate beneath the impurity region.

7. The phase change memory device according to claim 3, wherein the heat sinks comprise at least one of a tungsten layer, a tungsten silicide layer, and a titanium nitride layer.

8. The phase change memory device according to claim 3, further comprising:
a hard mask layer formed on sidewalls of the heaters.

9. The phase change memory device according to claim 8, further comprising:
an insulation layer interposed between the hard mask layer and the phase change layer.

10. The phase change memory device according to claim 9, wherein the insulation layer comprises a nitride layer.

11. The phase change memory device according to claim 3, further comprising:
upper electrodes formed on the phase change layer; and
a protective layer formed to cover the upper electrodes and the phase change layer.

12. A method for manufacturing a phase change memory device, comprising the steps of:
forming switching elements on a semiconductor substrate;
forming heat sinks on the switching elements;
forming heaters on the heat sinks; and
forming a phase change layer on the heaters.

13. The method according to claim 12, wherein the switching elements are formed as vertical PN diodes.

14. The method according to claim 12, wherein, before the step of forming the switching elements, the method further comprises the step of:
forming an impurity region within a surface of the semiconductor substrate.

15. The method according to claim 12, wherein the heat sinks comprise any one of a tungsten layer, a tungsten silicide layer, and a titanium nitride layer.

16. The method according to claim 12, wherein, after the step of forming the phase change layer, the method further comprises the steps of:
forming upper electrodes on the phase change layer; and
forming a protective layer to cover the upper electrodes and the phase change layer.

17. A method for manufacturing a phase change memory device, comprising the steps of:
providing a semiconductor having a cell region and a peripheral region;
forming an interlayer dielectric having contact holes on the cell region of the semiconductor substrate;
forming a first conductivity type polysilicon layer on the semiconductor substrate including the interlayer dielectric, such that the contact holes are filled with the first conductivity type polysilicon layer;
ion-implanting second conductivity type impurities into an upper portion of the first conductivity type polysilicon layer formed within the contact holes in the cell region so as to form vertical PN diodes;
forming a conductive layer on the semiconductor substrate including the cell region in which the vertical PN diodes are formed;
etching both the conductive layer and the first conductivity type polysilicon layer so as to form heat sinks on the vertical PN diodes in the cell region and form gates on the semiconductor substrate in the peripheral region;
forming heaters on the heat sinks in the cell region; and
forming a phase change layer on the heaters.

18. The method according to claim 17, wherein, before the step of forming the interlayer dielectric, the method further comprises the step of:
forming an impurity region within a surface of the semiconductor substrate in the cell region.

19. The method according to claim 17, wherein the step of forming the first conductivity type polysilicon layer comprises the steps of:
depositing a first conductivity type polysilicon layer on the semiconductor substrate including the interlayer dielectric to fill the contact holes; and
chemically mechanically polishing the first conductivity type polysilicon layer until the interlayer dielectric is exposed.

20. The method according to claim 17, wherein, after the step of forming the conductive layer and before the step of forming the heat sinks and the gates, the method further comprises the step of:
forming a hard mask layer on the conductive layer.

21. The method according to claim 17, wherein the heat sinks comprise at least one of a tungsten layer, a tungsten silicide layer, and a titanium nitride layer.

22. The method according to claim 17, wherein, after the step of forming the heat sinks and the gates and before the step of forming the heaters, the method further comprises the step of:
forming an insulation layer on the semiconductor substrate formed with the heat sinks and the gates to cover the heat sinks and the gates.

23. The method according to claim 22, wherein the insulation layer comprises a nitride layer.

24. The method according to claim 17, wherein, after the step of forming the phase change layer, the method further comprises the steps of:
forming upper electrodes on the phase change layer; and
forming a protective layer to cover the upper electrodes and the phase change layer.

25. A method for manufacturing a phase change memory device, comprising the steps of:
providing a semiconductor having a cell region and a peripheral region;
forming an interlayer dielectric having contact holes on the cell region of the semiconductor substrate, such that the contact holes expose portions of the cell region;
forming a first conductivity type epi-silicon layer in the contact holes in the cell region;
removing a portion of the interlayer dielectric formed in the peripheral region;
forming a polysilicon layer in the peripheral region from which the portion of the interlayer dielectric is removed;
ion-implanting second conductivity type impurities into an upper portion of the first conductivity type epi-silicon layer formed in the contact holes in the cell region so as to form vertical PN diodes;
forming a conductive layer on the semiconductor substrate including the cell region in which the vertical PN diodes are formed;
etching both the conductive layer and the polysilicon layer so as to form heat sinks on the vertical PN diodes in the cell region and form gates on the semiconductor substrate in the peripheral region;
forming heaters on the heat sinks in the cell region; and
forming a phase change layer on the heaters.

26. The method according to claim 25, wherein, before the step of forming the interlayer dielectric, the method further comprises the step of:
forming an impurity region within a surface of the semiconductor substrate in the cell region.

27. The method according to claim 26, wherein, before the step of forming the impurity region, the method further comprises the step of:
forming a punch stop ion implantation layer; and
forming a field stop ion implantation layer;
wherein the punch stop ion implantation layer and the field stop implantation layer are formed sequentially in the semiconductor substrate beneath the impurity region.

28. The method according to claim 25, wherein the step of forming the first conductivity type epi-silicon layer comprises the steps of:
growing a first conductivity type epi-silicon layer from the exposed portions of the cell region; and
chemically mechanically polishing the first conductivity type epi-silicon layer until the interlayer dielectric is exposed.

29. The method according to claim 25, wherein the step of forming the polysilicon layer in the peripheral region comprises the steps of:
depositing a polysilicon layer on the semiconductor substrate including the peripheral region from which the interlayer dielectric is removed; and
chemically mechanically polishing the polysilicon layer until the interlayer dielectric in the cell region is exposed.

30. The method according to claim 25, wherein the step of forming the polysilicon layer in the peripheral region comprises the steps of:
depositing a polysilicon layer on the semiconductor substrate including the peripheral region from which the interlayer dielectric is removed;
forming a mask pattern to expose a portion of the polysilicon layer formed in the cell region;
etching the portion of the polysilicon layer exposed in the cell region; and
removing the mask pattern.

31. The method according to claim 25, wherein, after the step of forming the conductive layer and before the step of forming the heat sinks and the gates, the method further comprises the step of:
forming a hard mask layer on the conductive layer.

32. The method according to claim 25, wherein the heat sinks comprise at least one of a tungsten layer, a tungsten silicide layer, and a titanium nitride layer.

33. The method according to claim 25, wherein, after the step of forming the heat sinks and the gates and before the step of forming the heaters, the method further comprises the step of:
forming an insulation layer on the semiconductor substrate formed with the heat sinks and the gates so as to cover the heat sinks and the gates.

34. The method according to claim 33, wherein the insulation layer comprises a nitride layer.

35. The method according to claim 25, wherein, after the step of forming the phase change layer, the method further comprises the steps of:
forming upper electrodes on the phase change layer; and
forming a protective layer to cover the upper electrodes and the phase change layer.
